(19) United States
(12) Patent Application Publication
(10) Pub. No.: US 2025/0218736 A1
(43) Pub. Date: Jul. 3, 2025

(54) APPARATUS AND METHOD FOR CONTROLLING TEMPERATURE

(71) Applicant: SEMES CO., LTD., Cheonan-si (KR)

(72) Inventors: Yun Sik JU, Yongin-si (KR); Chung Woo LEE, Suwon-si (KR)

(21) Appl. No.: 18/895,948

(22) Filed: Sep. 25, 2024

(30) Foreign Application Priority Data
Dec. 29, 2023 (KR) 10-2023-0196352

(51) Int. Cl. H01J 37/32

(52) U.S. Cl. CPC H01J 37/32522; H01J 2237/002; H01J 2237/24585

(57) ABSTRACT

The present disclosure provides an apparatus and a method for controlling a temperature. Provided is the apparatus for controlling a temperature, including: a chamber having a processing space inside; a substrate support unit disposed in the chamber and supporting a substrate; a heating unit including a heating member installed in an upper portion of the chamber and heating the upper portion of the chamber; a cooling unit including a cooling member installed in the upper portion of the chamber and cooling the upper portion of the chamber; and a controller controlling the heating unit and the cooling unit.

### CROSS-REFERENCE TO RELATED APPLICATION(S)

This application claims benefit of priority to Korean Patent Application No. 10-2023-0196352 filed on Dec. 29, 2023, in the Korean Intellectual Property Office, the disclosure of which is incorporated herein by reference in its entirety.

### BACKGROUND

### 1. Field

The present disclosure relates to an apparatus and method for controlling a temperature.

### 2. Description of Related Art

A semiconductor device manufacturing process may include a process of etching a surface of a substrate to form a desired pattern on the substrate. The etching process may be performed by causing ions or radicals included in plasma to collide with a thin film formed on the substrate or react with the thin film.

Plasma is mainly used in the etching process for forming a fine pattern. Plasma refers to matter in a gaseous state separated into ions, radicals, electrons, or the like, at a high temperature. Plasma is generated by significantly high temperature, strong electric fields, or high-frequency electromagnetic fields (RF electromagnetic fields).

An internal temperature or pressure of a chamber is controlled to control a plasma generation environment or the substrate processing environment performed using plasma. A heater and a chilling pipe may be installed in an upper portion of the chamber to control a temperature of the upper portion of the chamber. The temperature of the upper portion of the chamber may be rapidly increased using a heater, and the cooling speed may be controlled according to a temperature and a flow rate of refrigerant flowing in the chilling pipe.

In general, a heater and a chilling pipe installed in the upper portion of the chamber are independently controlled, but since the heater and the chilling pipe may interfere with each other, there may be a problem in which a temperature control deviation occurred depending on the operator controlling the heater and the chilling pipe.

### SUMMARY

An aspect of the present disclosure is to provide an apparatus and a method for controlling a temperature which can effectively improve temperature control performance of an upper portion of a chamber.

In an embodiment, the present disclosure is to provide an apparatus and a method for controlling a temperature which may secure robust temperature control performance from external disturbances by estimating a temperature of an upper portion of a chamber heated by a heating member and controlling a cooling member by feedforward compensation based on the estimated temperature of the upper portion of the chamber.

In an embodiment, the present disclosure is to provide an apparatus and a method for controlling a temperature which may quickly stabilize a temperature by deriving a compensation value for an opening rate of a flow rate control valve controlling a flow rate of refrigerant delivered to a refrigerant path based on an output of a heater controller for controlling a temperature of a heating member, and controlling the flow rate control valve.

In order to achieve the above-mentioned purpose, the present disclosure provides an apparatus and a method for controlling a temperature as follows.

In an embodiment of the present disclosure, provided an apparatus for controlling a temperature, including: a chamber having a processing space thereinside; a substrate support unit disposed in the chamber and supporting a substrate; a heating unit including a heating member installed in an upper portion of the chamber and heating the upper portion of the chamber; a cooling unit including a cooling member installed in the upper portion of the chamber and cooling the upper portion of the chamber; and a controller controlling the heating unit and the cooling unit, and the controller estimates a temperature of the upper portion of the chamber heated by the heating member and controls the cooling member based on the estimated temperature of the upper portion of the chamber to control the temperature of the upper portion of the chamber.

In an embodiment of the present disclosure, provided a method for controlling a temperature, including: heating an upper portion of a chamber by a heating member installed in the upper portion of the chamber; compensatingly controlling a cooling member installed in the upper portion of the chamber based on a temperature estimation value of the upper portion of the chamber heated by the heating member; and cooling the upper portion of the chamber by a cooling member installed in the upper portion of the chamber.

In an embodiment of the present disclosure, provided is a method for controlling temperature, including: measuring a temperature of an upper portion of a chamber by a temperature sensor installed in the upper portion of the chamber; heating the upper portion of the chamber with a heating member installed in the upper portion of the chamber; compensatingly controlling a cooling member installed in the upper portion of the chamber based on a temperature estimation value of the upper portion of the chamber heated by the heating member; and cooling the upper portion of the chamber by the cooling member installed in the upper portion of the chamber, and the compensatingly controlling a cooling member includes: deriving the temperature estimation value of the upper portion of the chamber based on a heater temperature estimation model; and calculating a compensation value of an opening rate of a flow rate control valve controlling a flow rate of refrigerant delivered to the cooling member.

The present disclosure may provide an apparatus and a method for controlling a temperature which can effectively improve temperature control performance of an upper portion of a chamber.

In an embodiment, the present disclosure may provide an apparatus and a method for controlling a temperature which may secure temperature control performance from external disturbances by estimating a temperature of an upper portion of a chamber heated by a heating member and controlling a cooling member by feedforward compensation based on the estimated temperature of the upper portion of the chamber.

In an embodiment, the present disclosure may provide an apparatus and a method for controlling a temperature which may quickly stabilize a temperature by deriving a compensation value for an opening rate of a flow rate control valve controlling a flow rate of refrigerant delivered to a refrigerant path based on an output of a heater controller for controlling a temperature of a heating member, and controlling the flow rate control valve

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 illustrates an apparatus for controlling a temperature according to an embodiment of the present disclosure;

FIG. 2 is a block diagram illustrating a controller of an apparatus for controlling a temperature according to an embodiment of the present disclosure;

FIG. 3 illustrates a control block diagram of a method for controlling a temperature according to Comparative Example;

FIG. 4 is an exemplary control block diagram illustrating some operations of a method for controlling a temperature according to an embodiment of the present disclosure;

FIG. 5 is an exemplary control block diagram illustrating some operations of a method for controlling a temperature according to an embodiment of the present disclosure;

FIG. 6 is an exemplary control block diagram illustrating some operations of a method for controlling a temperature according to an embodiment of the present disclosure;

FIG. 7A is a graph illustrating a temperature of an upper portion and a valve position of an apparatus for controlling a temperature according to Comparative Example;

FIG. 7B is an exemplary graph illustrating a temperature of an upper portion and a valve position of an apparatus for controlling a temperature according to an embodiment of the present disclosure; and

FIG. 8 is a flowchart of a method for controlling a temperature according to an embodiment of the present disclosure.

### DETAILED DESCRIPTION

Hereinafter, preferred example embodiments will be described in detail with reference to the accompanying drawings so that those of ordinary skill in the art may easily implement the present disclosure. However, in describing preferred example embodiments of the present disclosure in detail, when it is determined that a detailed description of related known functions or configurations may unnecessarily obscure the gist of the present disclosure, the detailed description thereof will be omitted. Furthermore, the same reference numbers are used throughout the drawings to refer to the same or similar functions and actions. In the present specification, it may be understood that the expressions such as “on,” “above,” “upper,” “below”, “beneath,” “lower,” and “side surface,” merely indicated based on drawings, and may actually vary depending on the direction in which the components are disposed.

Furthermore, throughout the specification, the terms “connected to” or “coupled to” are used to designate a connection or coupling of one element to another element and include both a case where an element is “directly connected or coupled to” another element and a case where an element is “indirectly connected or coupled to” another element via still another element. Furthermore, when a certain portion “comprises” a certain component, this “includes” or indicates that other components are not excluded and may be further included unless otherwise noted.

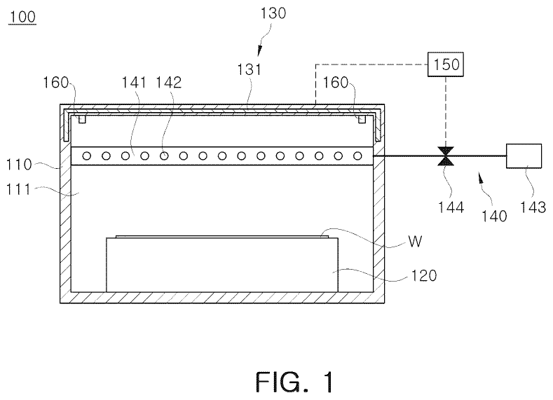

FIG. 1 illustrates an apparatus for controlling a temperature according to an embodiment of the present disclosure. Referring to FIG. 1, an apparatus 100 for controlling a temperature may include a chamber 110, a substrate support unit 120, a heating unit 130, a cooling unit 140, and a controller 150.

The apparatus 100 for controlling a temperature may be a substrate processing device performing processing on a substrate W using plasma. The processing on the substrate W may include, for example, an etching process.

The chamber 110 may have a processing space 111 formed therein. The processing space 111 may be an environment that may be controlled to an appropriate temperature and pressure to perform processing on the substrate W.

The substrate support unit 120 may be disposed in the chamber 110. The substrate support unit 120 may include a substrate support surface supporting the substrate W and adsorbing and fixing the substrate W.

The substrate support member 120 may receive a DC voltage and absorb the substrate W by electrostatic force. Additionally, the substrate support member 120 may be controlled to have a preset temperature in order to control processing of the substrate W.

The apparatus 100 for controlling a temperature may further include a plasma generating portion generating plasma in the processing space 111. The plasma generating portion may generate plasma from processing gas supplied to the processing space 111.

The heater member 130 may heat an upper portion of the chamber 110. The heater member 130 may include a heating member 131 installed in the upper portion of the chamber 110.

The heating member 131 may be installed in an appropriate arrangement form in an interior of a wall of the chamber 110 or on an inner surface of the chamber 110 in order to increase a temperature of the upper portion of the chamber 110. For example, the heating member 131 may be inserted and installed inside at least a portion of an upper wall and a side wall of the chamber 110.

The cooling member 140 may cool the upper portion of the chamber 110. The cooling member 140 may include a cooling member installed in the upper portion of the chamber 110. The cooling member may be implemented as, for example, a portion of a shower head.

The cooling member may be disposed in an upper side of the substrate support member 120 in the upper portion of the chamber 110.

The cooling member may include a plate 141 in which a refrigerant path 142 through which refrigerant flows is formed. The refrigerant path 142 may be formed in an appropriate arrangement form in the plate 141 in order to lower the temperature of the upper portion of the chamber 110 by the flow of the refrigerant.

The cooling member 140 may further include a refrigerant supply portion 143 and a flow rate control valve 144.

The refrigerant supply portion 143 may store the refrigerant and supply the refrigerant to the refrigerant path 142. The refrigerant supply portion 143 may control and maintain the temperature of the stored refrigerant.

The flow rate control valve 144 may be installed in a refrigerant supply line connected between the refrigerant supply portion 143 and the refrigerant path 142. The flow rate control valve 144 may control a flow rate of the refrigerant delivered from the refrigerant supply portion 143 to the refrigerant path 142 in the refrigerant supply line.

The controller 150 may control the temperature of the upper portion of the chamber 110 by controlling the heating unit 130 and the cooling unit 140.

Specifically, the controller 150 may estimate the temperature of the upper portion of the chamber 110 heated by the heating member 131. The controller 150 may control the cooling member based on the estimated temperature of the upper portion of the chamber 110.

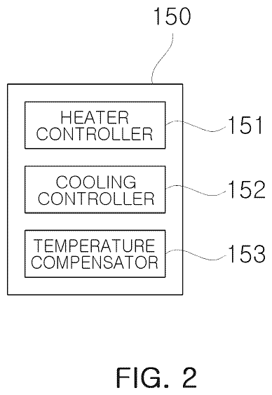

FIG. 2 is a block diagram illustrating a configuration of a controller 150. Referring to FIG. 2, the controller 150 may include a heater controller 151, a cooling controller 152, and a temperature compensator 153.

The heater controller 151 may control a temperature of the heating member 131. The controller 150 may control the temperature of the heating member 131 varying according to an output value of the heater controller 151 by controlling an output value of the heater controller 151.

That is, the controller 150 may control a degree of an increase in the temperature of the upper portion of the chamber 110 by controlling an output of the heater controller 151.

The apparatus 100 for controlling a temperature may further include a temperature sensor 160 installed at the upper portion of the chamber 110. The temperature sensor 160 may be, for example, an IR sensor measuring the temperature of the upper portion of the chamber 110 in a non-contact manner. Alternatively, the temperature sensor 160 may be a contact temperature measuring sensor.

The controller 150 may control the heater controller 151 to output a heater control value for controlling the temperature of the heating member 131. The heater control value may be determined based on a target temperature value of the upper portion of the chamber 110 and a measurement value of the temperature sensor 160.

The cooling controller 152 may control an opening rate of the flow rate control valve 144. The controller 150 may control an output value of the cooling controller 152 to control the opening rate of the flow rate control valve 144 varying according to an output value of the cooling controller 152, and may control the flow rate of the refrigerant delivered to the refrigerant path 142 based on the opening rate of the flow rate control valve 144.

That is, the controller 150 may control a degree of a decrease in the temperature of the upper portion of the chamber 110 by controlling the output of the cooling controller 152.

The controller 150 may control the cooling controller 152 based further on an output value of the temperature compensator 153. Specifically, the temperature compensator 153 may input a heater control value output from the heater controller 151, and output a compensation value for the opening rate of the flow rate control valve 144.

The controller 150 may control the cooling controller 152 based on the opening rate of the flow rate control valve 144 according to the target temperature value of the upper portion of the chamber 110 and the compensation value for the opening rate of the flow rate control valve 144 output from the temperature compensator 153.

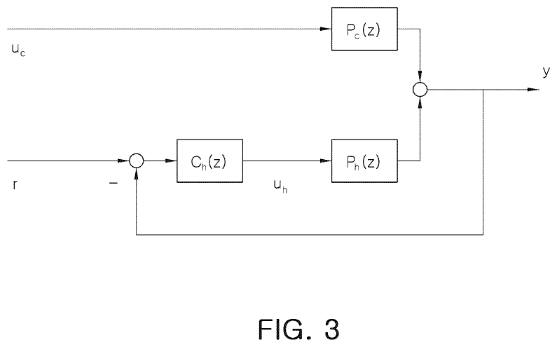

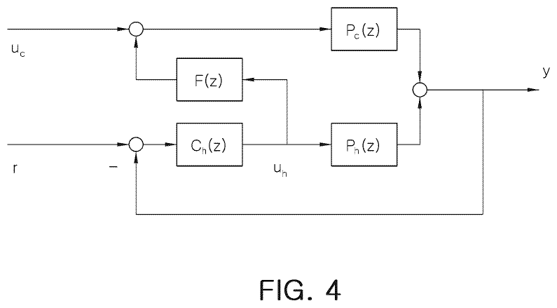

FIG. 3 illustrates a control block diagram of a method for controlling a temperature according to Comparative Example, and FIG. 4 illustrates a control block diagram of a method for controlling a temperature according to an embodiment of the present disclosure.

In FIGS. 3 and 4, u_{c} may represent an opening rate of a flow rate control valve 144 according to a target temperature value of the upper portion of the chamber 110, Pc (z) may represent a temperature model of a cooling member, r may represent a target temperature value, Cₕ(z) may represent a model of a heater controller 151, un may represent a heater control value output from the heater controller 151, Pₕ(z) may represent a temperature model of a heating member 131, and y may represent a temperature of the upper portion of the chamber 110.

As illustrated in FIG. 3, the control of the cooling member and the control of the heating member can be performed independently of each other. A temperature control of the upper portion of the chamber 110 may be performed by combining a control result of the cooling member and a control result of the heating member, which are performed independently of each other.

As illustrated in FIG. 3A, in the control of the cooling member and the control of the heating member, which are performed independently of each other, the method for controlling the temperature according to the present disclosure may additionally perform feedforward compensation control of the cooling member based on the heater control value for controlling the heating member, thereby improving temperature control performance of the upper portion of the chamber 110.

Specifically, in FIG. 4, F(z) may represent a model of a temperature compensator 153, which may perform feedforward compensation control. F(z) may receive a heater control value (uₕ) output from a heater controller 151 and may output a compensation value for the opening rate of the flow rate control valve 144.

As illustrated in FIG. 4, the cooling member may be controlled based on the opening rate (u_{c}) of the flow rate control valve 144 according to the target temperature value of the upper portion of the chamber 110 and the compensation value for the opening rate of the flow rate control valve 144 output from the temperature compensator 153,

The temperature compensator 153 may derive the compensation value for the opening rate of the flow rate control valve 144 based on the heater temperature estimation model and a proportional constant (K). The heater temperature estimation model may derive the temperature estimation value of the upper portion of the chamber 110 heated by the heating member 131. The proportional constant (K) may be a constant based on a relationship between the temperature of the upper portion of the chamber 110 and the opening rate of the flow rate control valve 144.

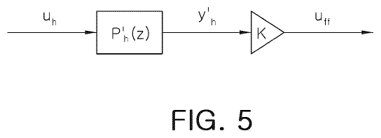

FIG. 5 illustrates an example of a control block diagram implementing the model (F(z)) of a temperature compensator 153 in a method for controlling a temperature according to an embodiment of the present disclosure.

In FIG. 5, Un may represent a heater control value output from the heater controller 151, P′ₕ(z) may represent a mathematical model of the heating member 131, y′ₕ may represent a temperature estimation value of the upper portion of the chamber 110 heated by the heating member 131, K may represent a proportional constant between the temperature of the upper portion of the chamber 110 and the opening rate of the flow rate control valve 144, and u_{ff} may represent a compensation value for the opening rate of the flow rate control valve 144.

P′ₕ(z) may represent a mathematical model of the heating member 131, and may be a heater temperature estimation model for deriving the temperature estimation value of the upper portion of the chamber 110 heated by the heating member 131. As illustrated in FIG. 5, P′ₕ(z) may receive a heater control value (uₕ) and may derive a temperature estimation value (y′h) of the upper portion of the chamber 110 heated by the heating member 131.

The temperature compensator 153 may derive a compensation value (u_{ff}) for the opening rate of the flow rate control valve 144 based on a temperature estimation value (y′ₕ) of the upper portion of the chamber 110 and a proportional constant (K) between the temperature of the upper portion of the chamber 110 and the opening rate of the flow rate control valve 144.

The temperature compensator 153 may include a differentiator configured to derive a variation amount of the temperature estimation value of the upper portion of the chamber 110 and an integrator configured to derive an accumulated value of the variation amount of the temperature estimation value of the upper portion of the chamber 110.

The temperature compensator 153 may derive a compensation value for the opening rate of the flow rate control valve 144 further based on a first weight (K₁) and a second weight (K₂). For example, the temperature compensator 153 may apply the first weight (K₁) to the variation amount of the temperature estimation value of the upper portion of the chamber 110 output from the differentiator, and may apply the second weight (K₂) to the accumulated value of the variation amount of the temperature estimation value of the upper portion of the chamber 110 output from the integrator.

The temperature compensator 153 may be set so that a value obtained by multiplying the first weight (K₁) and the second weight (K₂) has the same value as that of the proportional constant (K) between the temperature of the upper portion of the chamber 110 and the opening rate of the flow rate control valve 144.

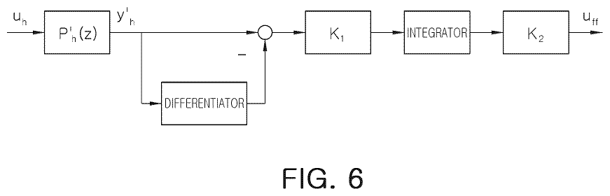

FIG. 6 illustrates another example of a control block diagram implementing a model (F(z)) of a temperature compensator 153 in a method for controlling a temperature according to an embodiment of the present disclosure.

In FIG. 6, un may represent a heater control value output from the heater controller 151, P′ₕ(z) may represent a mathematical model of the heating member 131, y′ₕ may represent a temperature estimation value of the upper portion of the chamber 110 heated by the heating member 131, K₁ may represent a first weight applied to a variation amount of the temperature estimation value of the upper portion of the chamber 110, K₂ may represent a second weight applied to the accumulated value of the variation amount of the temperature estimation value of the upper portion of the chamber 110, and u_{ff} may represent a compensation value for the opening rate of the flow rate control valve 144.

P′ₕ(z) may represent a mathematical model of the heating member 131, and may be a heater temperature estimation model for deriving a temperature estimation value of the upper portion of the chamber 110 heated by the heating member 131. A s illustrated in FIG. 6, P′ₕ(z) may receive a heater control value (uₕ) and may derive a temperature estimation value (y′ₕ) of the upper portion of the chamber 110 heated by the heating member 131.

The temperature compensator 153 of FIG. 6 may further include a differentiator and an integrator by utilizing multi-rate.

The differentiator may receive the temperature estimation value (y′h) of the upper portion of the chamber 110 heated by the heating member 131 and may output the variation amount of the temperature estimation value of the upper portion of the chamber 110. The variation amount of the temperature estimation value of the upper portion may be expressed as in Equation 1. In Equation 1, y′ₕ[n] represents a current temperature estimation value of the upper portion, and y′ₕ[n−1] represents a previous temperature estimation value of the upper portion.

$$Δ y = {y}_{h}^{′} [ n ] - {y}_{h}^{′} [ n - 1 ] \qquad Equation 1$$

Additionally, the integrator may receive an output of the differentiator to which the first weight (K₁) is applied and may output the accumulated value of the variation amount of the temperature estimation value of the upper portion of the chamber 110. The accumulated value of the variation amount of the temperature estimation value of the upper portion may be approximated as in Expression 2.

$$\sum Δ y ≅ \frac{1}{1 - {z}^{- 1}} \qquad Equation 2$$

The temperature compensator 153 may derive the compensation value (u_{ff}) for the opening rate of the flow rate control valve 144 by applying the second weight (K₂) to the accumulated value of the variation amount of the temperature estimation value of the upper portion of the chamber 110 output from the integrator.

The temperature compensator 153 of FIG. 6 may be set so that a value obtained by multiplying the first weight (K₁) and the second weight (K₂) has the same value as the proportional constant (K) between the temperature of the upper portion of the chamber 110 and the opening rate of the flow rate control valve 144 of the temperature compensator 153 illustrated in FIG. 5.

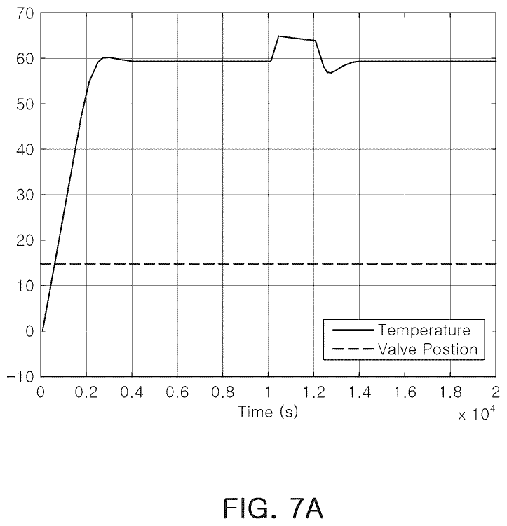

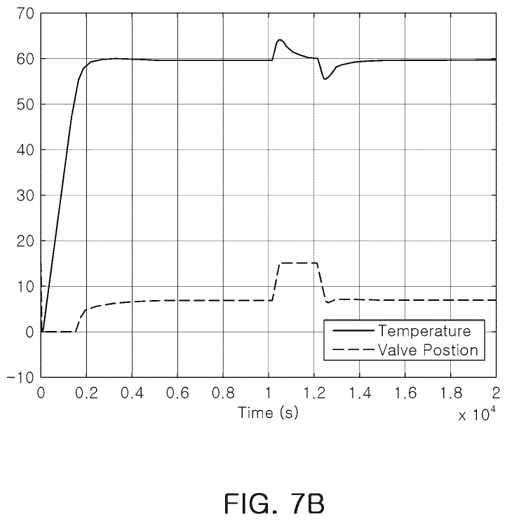

FIG. 7A is a graph illustrating a temperature of an upper portion and a valve position of an apparatus for controlling a temperature according to Comparative Example, and FIG. 7B is an exemplary graph illustrating a temperature of an upper portion and a valve position of an apparatus 100 for controlling a temperature according to an embodiment of the present disclosure. In FIGS. 7A and 7B, the valve position may refer to an opening rate of a refrigerant control valve controlling a flow rate of refrigerant delivered to a refrigerant path of a cooling member.

In the graph of FIG. 7A, the valve position does not change even in a section in which the temperature of the upper portion changes, but in the graph of FIG. 7B, the valve position changes in real time in a section in which the temperature of the upper portion changes. That is, according to a method for controlling a temperature according to an embodiment of the present disclosure, the opening rate of the refrigerant control valve may be controlled more flexibly in response to changes in the temperature of the upper portion of the chamber.

The present disclosure may control the heating member 131 based on the measurement value of the temperature sensor 160 disposed on the upper portion of the chamber 110, and may compensatingly control the cooling member in a feed-forward manner based on the output value of the heater controller 151 for controlling the temperature of the heating member 131, thereby precisely controlling and quickly stabilized the temperature of the upper portion of the chamber 110.

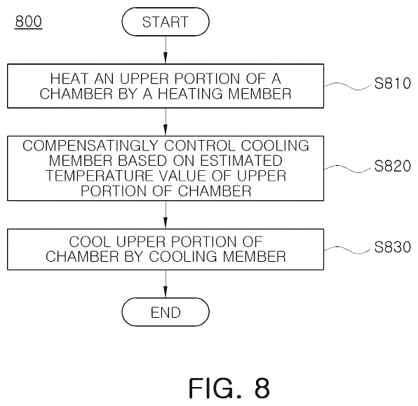

FIG. 8 is a flow chart of a method for controlling a temperature according to an embodiment of the present disclosure. Referring to FIG. 8, a method for controlling a temperature may include an operation of heating an upper portion of a chamber by a heating member (S810), an operation of compensatingly controlling a cooling member based on an estimated temperature value of the upper portion of the chamber (S820), and an operation of cooling the upper portion of the chamber by the cooling member (S830).

The operation of heating the upper portion of the chamber (S810) may include an operation of controlling an output of a heater controller for controlling a temperature of the heating member. The temperature of the heating member may be controlled by a heater control value output from the heater controller.

The method 800 for controlling the temperature may further include an operation of measuring the temperature of the upper portion of the chamber by a temperature sensor installed in the upper portion of the chamber.

The operation of heating the upper portion of the chamber (S810) may further include an operation of setting a target temperature value of the upper portion of the chamber, and an operation of calculating a heater control value output from the heater controller based on a target temperature value and a measurement value of the temperature sensor.

The operation of compensating and controlling the cooling member (S820) may further include an operation of controlling an opening rate of a flow rate control valve controlling a flow rate of refrigerant delivered to the operation of calculating refrigerant path, and an a compensation value for the opening rate of the flow rate control valve based on the heater control value.

In the operation of calculating the compensation value for the opening rate of the flow rate control valve, the compensation value may be derived based further on a heater temperature estimation model for deriving a temperature estimation value of the upper portion of the chamber heated by the heating member, and a proportional constant between the temperature of the upper portion of the chamber and the opening rate of the flow rate control valve.

The operation of calculating the compensation value for the opening rate of the flow rate control valve may include: an operation of deriving a variation amount of the temperature estimation value of the upper portion of the chamber, an operation of applying a first weight to the variation amount of the temperature estimation value of the upper portion of the chamber, an operation of deriving an accumulated value of the variation amount of the temperature estimation value of the upper portion of the chamber, and an operation of applying a second weight to the accumulated value of the variation amount of the temperature estimation value of the upper portion of the chamber.

In the operation of calculating the compensation value for the opening rate of the flow rate control valve, a value obtained by multiplying the first weight and the second weight may be set to have the same value as that of a proportional constant between the temperature of the upper portion of the chamber and the opening rate of the flow rate control valve.

Additionally, in describing the present disclosure, ‘˜ portion’ or ‘unit’ may be implemented in various manners, for example, by a processor, program instructions executed by the processor, a software module, a microcode, a computer program product, a logic circuit, an application-specific integrated circuit, firmware, or the like.

The contents of the method disclosed in the embodiment of the present application may be directly implemented by a hardware processor, or may be implemented and performed by a combination of hardware and software modules among the processors. The software module may be stored in a conventional storage medium such as a random-access memory, a flash memory, a read-only memory, a programmable read-only memory, an electrically erasable programmable memory, a register, or the like. The storage medium is disposed in the memory, and the processor reads the information stored in the memory and combines the information with the hardware to complete the contents of the above-described method. In order to avoid duplication, a detailed description is omitted here.

In the implementation process, each content of the above-described method may be completed by a logical integrated circuit of the hardware among the processors or an instruction in the form of software.

That is, those skilled in the art may recognize that each exemplary unit and algorithm operation described in the embodiments disclosed herein may be realized by combining electronic hardware or a combination of computer software and electronic hardware. Whether such a function is performed in a hardware manner or in a software manner is determined by the specific application and design constraints of the technical solution. Those skilled in the art may realize the described function using different methods for each specific application, but such realization should not be considered as being outside the scope of the present application.

It should be understood that in the several embodiments provided in the present application, the disclosed apparatus and method may be realized in other manners. For example, the apparatus embodiments described above are merely exemplary, for example, the division of the units is merely a kind of logical functional division, and other division methods may exist in actual implementation, and for example, a plurality of units or assemblies may be combined or integrated into another system, or some features may be ignored or not performed. On the other hand, the coupling or direct coupling or communication connection between each other displayed or discussed may be an indirect coupling or communication connection through some interface, apparatus or unit, and may be provided in an electrical, mechanical or other form.

The unit described as a separate component above may be physically separated, and the component displayed as a unit may or may not be a physical unit, that is, disposed in one point or distributed in a plurality of network units. Some or all of the units may be selected according to actual needs to realize the purpose of the solution of the present embodiment.

That is, each functional unit in each embodiment of the present application may be integrated into one processing unit, and each unit may exist alone, or two or more units may be integrated into one unit.

When the function is implemented in the form of a software functional unit and sold or used as an independent product, this may be stored in one computer-readable storage medium. Based on this understanding, a portion that essentially contributes to the prior art in technical solution of the present application, or a portion of the technical solution, may be implemented in the form of a software product, and the computer software product is stored in one storage medium, and includes a few instructions to cause one computer device (which may be a personal computer, a server, or a network device, or the like) to perform all or part of the operations of the method described in each embodiment of the present application. The storage medium described above includes various media capable of storing program codes, such as a USB memory, a mobile hard disk, a read-only memory (ROM), a random-access memory (RAM), a magnetic disk, a CD-ROM or the like.

The present disclosure is not limited to the embodiment described above and the accompanying drawings. The scope of rights of the present disclosure is intended to be limited by the appended claims. It will be understood by those skilled in the art that various substitutions, modification and changes in form and details may be made therein without departing from the spirit and scope of the present disclosure as defined by the appended claims.

What is claimed is:

1. An apparatus for controlling a temperature, comprising:
a chamber having a processing space inside;
a substrate support unit disposed in the chamber and supporting a substrate;
a heating unit including a heating member installed in an upper portion of the chamber and heating the upper portion of the chamber;
a cooling unit including a cooling member installed in the upper portion of the chamber and cooling the upper portion of the chamber; and
a controller controlling the heating unit and the cooling unit,
wherein the controller estimates a temperature of the upper portion of the chamber heated by the heating member and controls the cooling member based on the estimated temperature of the upper portion of the chamber to control the temperature of the upper portion of the chamber.

2. The apparatus for controlling a temperature according to claim 1, wherein the cooling member includes a plate having a refrigerant path formed therein through which a refrigerant flows, and
wherein the cooling unit further includes a flow rate control valve controlling a flow rate of the refrigerant delivered to the refrigerant path.

3. The apparatus for controlling a temperature according to claim 2, wherein the controller includes:
a heater controller controlling a temperature of the heating member; and
a cooling controller controlling an opening rate of the flow rate control valve.

4. The apparatus for controlling a temperature according to claim 3, further comprising:
a temperature sensor installed in the upper portion of the chamber,
wherein the heater controller outputs a heater control value for controlling the heating member based on a target temperature value of the upper portion of the chamber and a measurement value of the temperature sensor.

5. The apparatus for controlling a temperature according to claim 4, wherein the controller further includes a temperature compensator inputting the heater control value and outputting a compensation value for the opening rate of the flow rate control valve.

6. The apparatus for controlling a temperature according to claim 5, wherein the temperature compensator is configured to,
derive the compensation value based on a heater temperature estimation model for deriving a temperature estimation value of the upper portion of the chamber heated by the heating member, and a proportional constant between the temperature of the upper portion of the chamber and the opening rate of the flow control valve.

7. The apparatus for controlling a temperature according to claim 6, wherein the temperature compensator includes:
a differentiator configured to derive a variation amount of a temperature estimation value of the upper portion of the chamber; and
an integrator configured to derive an accumulated value of the variation amount of the temperature estimation value of the upper portion of the chamber.

8. The apparatus for controlling a temperature according to claim 7, wherein the temperature compensator is configured to
derive the compensation value based further on a first weight applied to an output of the differentiator, and a second weight applied to an output of the integrator.

9. The apparatus for controlling a temperature according to claim 8, wherein the temperature compensator is set so that a value obtained by multiplying the first weight and the second weight has the same value as the proportional constant.

10. A method for controlling a temperature, comprising:
heating an upper portion of a chamber by a heating member installed in the upper portion of the chamber;
compensatingly controlling a cooling member installed in the upper portion of the chamber based on a temperature estimation value of the upper portion of the chamber heated by the heating member; and
cooling the upper portion of the chamber by a cooling member installed in the upper portion of the chamber.

11. The method for controlling a temperature according to claim 10, wherein the cooling member includes a plate having a refrigerant path formed therein through which refrigerant flows, and
wherein the compensatingly controlling a cooling member includes,
controlling an opening rate of a flow rate control valve controlling a flow rate of the refrigerant delivered to the refrigerant path.

12. The method for controlling a temperature according to claim 11, wherein the heating an upper portion of a chamber includes,
controlling an output of a heater controller controlling a temperature of the heating member.

13. The method for controlling a temperature according to claim 12, further comprising:
measuring a temperature of the upper portion of the chamber by a temperature sensor installed in the upper portion of the chamber,
wherein the heating an upper portion includes:
setting a target temperature value of the upper portion of the chamber; and
calculating a heater control value output from the heater controller based on the target temperature value and a measurement value of the temperature sensor.

14. The method for controlling a temperature according to claim 13, wherein the compensatingly controlling a cooling member further includes, calculating a compensation value for the opening rate of the flow rate control valve based on the heater control value.

15. The method for controlling a temperature according to claim 14, wherein in the calculating compensation value,
the compensation value is derived based further on a heater temperature estimation model for deriving a temperature estimation value of the upper portion of the chamber heated by the heating member, and a proportional constant between the temperature of the upper portion of the chamber and the opening rate of the flow rate control valve.

16. The method for controlling a temperature according to claim 15, wherein the calculating a compensation value includes:
deriving a variation amount of the temperature estimation value of the upper portion of the chamber; and
deriving an accumulated value of the variation amount of the temperature estimation value of the upper portion of the chamber.

17. The method for controlling a temperature according to claim 16, wherein the calculating a compensation value further includes:
applying a first weight to the variation amount of the temperature estimation value of the upper portion of the chamber; and
applying a second weight to the accumulated value of the variation amount of the temperature estimation value of the upper portion of the chamber.

18. The method for controlling a temperature according to claim 17, wherein a value obtained by multiplying the first weight and the second weight is set to have the same value as a value of the proportional constant.

19. A method for controlling a temperature, comprising:
measuring a temperature of an upper portion of a chamber by a temperature sensor installed in the upper portion of the chamber;
heating the upper portion of the chamber with a heating member installed in the upper portion of the chamber;
compensatingly controlling a cooling member installed in the upper portion of the chamber based on a temperature estimation value of the upper portion of the chamber heated by the heating member; and
cooling the upper portion of the chamber by the cooling member installed in the upper portion of the chamber,
wherein the compensatingly controlling a cooling member includes:
deriving the temperature estimation value of the upper portion of the chamber based on a heater temperature estimation model; and
calculating a compensation value of an opening rate of a flow rate control valve controlling a flow rate of refrigerant delivered to the cooling member.

20. The method for controlling a temperature according to claim 19, wherein the calculating a compensation value includes:
deriving a variation amount of the temperature estimation value of the upper portion of the chamber;
applying a first weight to the variation amount of the temperature estimation value of the upper portion of the chamber;
deriving an accumulated value of the variation amount of the temperature estimation value of the upper portion of the chamber; and
applying a second weight to the accumulated value of the variation amount of the temperature estimation value of the upper portion of the chamber.
